(19) United States
(12) Patent Application Publication
(10) Pub. No.: US 2020/0411790 A1
(43) Pub. Date: Dec. 31, 2020

(54) FLEXIBLE COMPONENT, ELECTRONIC DEVICE, AND METHOD FOR DETACHING FLEXIBLE COVER

(71) Applicant: SHENZHEN ROYOLE TECHNOLOGIES CO., LTD., Shenzhen (CN)

(72) Inventors: Shengshan WEN, Shenzhen (CN); Kun ZHANG, Shenzhen (CN); Wen-Chieh SHIH, Shenzhen (CN)

(21) Appl. No.: 17/020,302

(22) Filed: Sep. 14, 2020

Related U.S. Application Data
(63) Continuation of application No. PCT/CN2018/079629, filed on Mar. 20, 2018.

(51) Int. Cl. H01L 51/52; H01L 27/32; H01L 51/00; H01L 51/56

(52) U.S. Cl. CPC H01L 51/524; H01L 27/323; H01L 27/3244; H01L 51/0097; H01L 2251/5338; H01L 51/5284; H01L 51/529; H01L 51/56; H01L 51/5281

(57) ABSTRACT

A flexible component is provided. The flexible component includes an adherence reduction layer for bonding. As the flexible component includes the adherence reduction layer, it is possible to facilitate bonding of the flexible component and detaching of a flexible cover from the flexible component. Also provided are an electronic device and a method for detaching a flexible cover.

### CROSS-REFERENCE TO RELATED APPLICATION(S)

This application is a continuation of International Application No. PCT/CN2018/079629, filed on Mar. 20, 2018, the entire disclosure of which is hereby incorporated by reference.

### TECHNICAL FIELD

This disclosure relates to the technical field of flexible display, and particular to a flexible component, an electronic device, and a method for detaching a flexible cover.

### BACKGROUND

Flexible display devices are made of flexible materials, which can be bent. In addition, the flexible display device also has characteristics such as low power consumption and light weight, and has a wide range of application prospects. The flexible display device has a display panel, which includes a flexible cover for protection. After a period of use, the flexible cover needs to be replaced due to scratches, cracks, etc. However, since an adhesive layer on the flexible cover usually has a large adhesion force, it is difficult to detach the flexible cover or is easy to cause damage to other devices of the display panel during detaching.

### SUMMARY

To solve the above problems, implementations of the disclosure provide a flexible component with an easy-to-detach flexible cover, an electronic device, and a method for detaching a flexible cover.

A flexible component is provided. The flexible component includes an adherence reduction layer for bonding.

In at least one implementation, the adherence reduction layer has an adhesion force, which is decreased in response to a first condition.

In at least one implementation, the first condition includes at least one of ultraviolet light irradiation, infrared light irradiation, laser irradiation, applying an electric field, applying a force field, applying a magnetic field, and heating.

In at least one implementation, the adherence reduction layer includes one of the following which is doped with photoresponsive supramolecules: acrylate, silica gel, rubber, or polyurethane, and the adhesion force is decreased when the adherence reduction layer is irradiated with ultraviolet light.

In at least one implementation, the adherence reduction layer includes one of acrylate, silica gel, rubber, or polyurethane, where the adhesion force is decreased because of generation of nitrogen when the acrylate is irradiated with ultraviolet light.

In at least one implementation, the flexible component further includes a protective layer, and the adherence reduction layer and the protective layer are stacked.

In at least one implementation, the protective layer is used to reduce energy transfer along a stacking direction of the protective layer relative to the adherence reduction layer.

In at least one implementation, the protective layer includes an energy absorption layer, energy input under the first condition being absorbed via the protective layer.

In at least one implementation, the energy absorption layer includes one of the following added with reinforced fibers: a polyethylene terephthalate compound, a cyclo-olefin polymer, or a polymethyl methacrylate compound.

In at least one implementation, the energy absorption layer is doped with organic heterocyclic compounds.

In at least one implementation, the energy absorption layer is made of at least one of amorphous silicon, indium tin oxide, indium gallium zinc oxide, aluminum titanium oxide, and porous silica gel.

In at least one implementation, the protective layer includes a heat dissipation layer, energy input under the first condition including heat, where the heat dissipation layer is used to block heat transfer along a stacking direction of the protective layer relative to the adherence reduction layer and emit heat along a direction perpendicular to the stacking direction of the protective layer relative to the adherence reduction layer.

In at least one implementation, the heat dissipation layer is made of at least one of thermally conductive graphene, thermally conductive adhesive, thermally conductive silicone, thermally conductive silica gel, thermally conductive rubber, and thermally conductive molybdenum sulfide.

In at least one implementation, the flexible component includes a flexible cover and a flexible module which are stacked, where the flexible cover or the flexible module includes the adherence reduction layer and the flexible cover is adhered to the flexible module via the adherence reduction layer.

In at least one implementation, the protective layer is located in the flexible cover and is located on one side of the adherence reduction layer away from the flexible module.

In at least one implementation, the flexible cover further includes a substrate, where the substrate is sandwiched between the adherence reduction layer and the protective layer.

In at least one implementation, the flexible cover further includes a substrate, where the substrate is disposed on one side of the protective layer away from the adherence reduction layer.

In at least one implementation, the substrate is made of at least one of mixtures such as polyethylene terephthalate, polyimide, cyclo-olefin polymer, polymethyl methacrylate, epoxy resin compound, organic alcohol ester, and inorganic amine.

In at least one implementation, the protective layer is located in the flexible module and the adherence reduction layer is located on one side of the protective layer adjacent to the flexible cover.

In at least one implementation, the flexible module further includes an optical adhesive layer, where the optical adhesive layer is located on one side of the protective layer away from the flexible cover.

In at least one implementation, the flexible cover further includes a shielding layer, where the shielding layer is formed on one side of the protective layer away from the adherence reduction layer and has a patterned shape.

In at least one implementation, the flexible cover further includes an optical adhesive layer, where the optical adhesive layer is disposed on one side of the adherence reduction layer away from the flexible module.

In at least one implementation, the flexible module further includes a shielding layer, where the shielding layer is formed on one side of the protective layer away from the flexible cover and has a patterned shape.

In at least one implementation, the flexible module further includes at least one functional layer, where the at least one functional layer is disposed on one side of the protective layer away from the adherence reduction layer.

In at least one implementation, where the at least one functional layer includes a display function layer.

In at least one implementation, the at least one functional layer includes a touch layer.

In at least one implementation, the adherence reduction layer includes at least one of: an ultraviolet adherence reduction layer, an infrared adherence reduction layer, a laser adherence reduction layer, a force adherence reduction layer, an electric adherence reduction layer, a magnetic adherence reduction layer, and a thermal adherence reduction layer.

In at least one implementation, the flexible module includes a display function layer and a support layer which are stacked, where the display function layer is disposed between the adherence reduction layer and the support layer.

In at least one implementation, the display function layer includes a polarizing layer, a thin film transistor layer, and an organic light emitting layer which are stacked sequentially, where the polarizing layer is disposed adjacent to the adherence reduction layer.

In at least one implementation, the flexible module further includes a touch layer, where the touch layer is disposed on one side of the display function layer away from the support layer and is bonded with the adherence reduction layer.

An electronic device is provided. The electronic device includes the flexible component of the above.

A method for detaching a flexible cover is provided. The method includes the following.

A first condition is applied to a component having the flexible cover and energy is provided to an adherence reduction layer of the component, to decrease adhesion face of the adherence reduction layer. The flexible cover is detached from the component.

In at least one implementation, the first condition includes at least one of ultraviolet light irradiation, infrared light irradiation, laser irradiation, applying an electric field, applying a force field, applying a magnetic field, and heating.

In at least one implementation, the adhesion force of the adherence reduction layer is decreased from 0.1˜3 kg/inch to 100 g/inch or less.

In at least one implementation, when the flexible cover is detached from the component, an angle at which the flexible cover is torn off from the component is in a range of 10 to 80 degrees.

In at least one implementation, when the flexible cover is detached from the component, a speed at which the flexible cover is torn off from the component is in a range of 100 to 1000 mm/min.

In at least one implementation, the component includes a flexible module and the flexible cover is bonded to the flexible module via the adherence reduction layer.

According to the flexible component, the electronic device, and the method of the implementations, as the flexible component includes the adherence reduction layer, it is possible to facilitate bonding of the flexible component and detaching of the flexible cover from the flexible component. Furthermore, under the first condition (such as, ultraviolet light irradiation/infrared light irradiation/laser irradiation/heating/applying force/applying electricity/applying magnetism, etc.), the adhesion force of the adherence reduction layer to the flexible module is decreased, which facilitates replacement of the flexible cover of the flexible component and is less likely to cause damage to the flexible component.

### BRIEF DESCRIPTION OF THE DRAWINGS

To describe technical solutions in implementations of the present disclosure more clearly, the following briefly introduces accompanying drawings required for illustrating the implementations. Apparently, the accompanying drawings in the following description illustrate some implementations of the present disclosure. Those of ordinary skill in the art may also obtain other drawings based on these accompanying drawings without creative efforts.

FIG. 1 is a schematic cross-sectional view illustrating a flexible component according to a first implementation.

FIG. 2 is a schematic cross-sectional view illustrating a flexible component according to an implementation.

FIG. 3 is a schematic cross-sectional view illustrating a flexible component according to a second implementation.

FIG. 4 is a schematic cross-sectional view illustrating a flexible component according to a third implementation.

FIG. 5 is a schematic cross-sectional view illustrating a flexible component according to a fourth implementation.

FIG. 6 is a schematic cross-sectional view illustrating a flexible component according to a fifth implementation.

FIG. 7 is a schematic diagram illustrating the flexible cover of FIG. 6 with a release film layer and a protective film layer.

FIG. 8 is a schematic cross-sectional view illustrating a flexible component according to a sixth implementation.

FIG. 9 is a schematic cross-sectional view illustrating a flexible component according to a seventh implementation.

FIG. 10 is a schematic diagram illustrating an electronic device with a flexible component.

FIG. 11 is a schematic flowchart illustrating a method for detaching according to implementations.

### DETAILED DESCRIPTION

Technical solutions in implementations of the present disclosure will be described clearly and completely hereinafter with reference to the accompanying drawings described in the previous chapter. Apparently, the described implementations are merely some rather than all implementations of the present disclosure. All other implementations obtained by those of ordinary skill in the art based on the implementations of the present disclosure without creative efforts shall fall within the protection scope of the present disclosure.

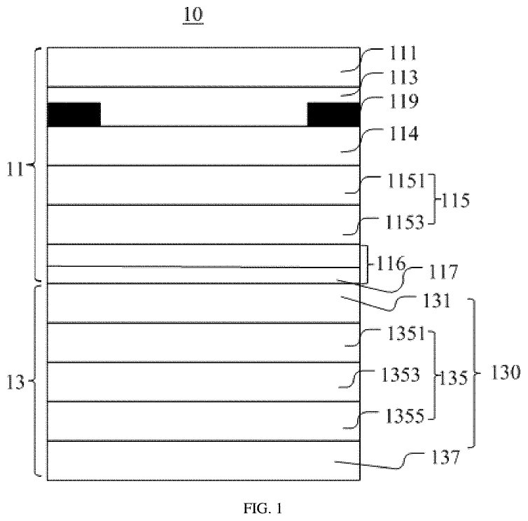

Referring to FIG. 1, a first implementation provides a flexible component 10. The flexible component 10 includes a flexible cover 11 and a flexible module 13. The flexible cover 11 is attached to the flexible module 13 to protect the flexible module 13. In this implementation, the flexible module 13 is a flexible display module. In other implementations, the flexible module 13 may be a flexible touch module or include both a flexible display module and a flexible touch module. The flexible cover 11 can be attached to other modules or structures, such as a rigid display module or a rigid touch module. In some examples, the flexible cover 11 can also be disposed on a back shell of an electronic device such as a mobile phone, a tablet computer, etc., to serve as a protective cover of the back shell.

The flexible cover 11 provides a hard layer 111 on one side of the flexible cover 11, and a connecting layer 116 on the other side of the flexible cover 11 away from the hard layer 111. The flexible cover 11 and the flexible module 13 are connected together via the connecting layer 116. In this implementation, the connecting layer 116 includes an adherence reduction layer 117, and the flexible cover 11 and the flexible module 13 are bonded together via the adherence reduction layer 117. In other implementations, the connecting layer 116 may be a bonding layer, a support layer, or other layers that have a connecting function.

In an example, the flexible cover 11 further includes at least one of a substrate 113, an optical adhesive layer 114, and a protective layer 115. The at least one of the substrate 113, the optical adhesive layer 114, and the protective layer 115 are sandwiched between the hard layer 111 and the adherence reduction layer 117. The hard layer 111 can be formed by coating a hard coating material on a layer structure furthest away from the adherence reduction layer 117, to enhance strength, hardness, and wear resistance of the flexible cover 11. The hard layer 111 includes organic compounds such as acrylic esters and polyethylene terephthalate, and inorganic compounds such as titanium nitride, aluminum carbonitride titanium compound, and tungsten sulfide. In the example, a coating technique is used to form the hard layer 111 on one side of the substrate 113 away from the adherence reduction layer 117. The coating technology may be: roll to roll coating, spin coating, slit and spin coating, slit coating, etc. When the hard layer 117 is made of organic compound, a chemical vapor deposition (CVD) technology or a physical vapor deposition (PVD) technology can be used. When the hard layer 117 is made of conductive material, technologies such as sputtering, ink jet printing, screen printing, and the like can be used.

According to the implementation illustrated in FIG. 1, the flexible cover 11 includes the hard layer 111, the substrate 113, the optical adhesive layer 114, the protective layer 115, and the connecting layer 116 which are stacked sequentially. The hard layer 111 is formed by coating the substrate 113 with a hard coating material, to enhance the strength, hardness, wear resistance, and scratch resistance of the flexible cover 11.

In other implementations, the flexible cover 11 may only include the substrate 113 and the optical adhesive layer 114 which are stacked between the hard layer 111 and the adherence reduction layer 117, or may only include the protective layer 115 sandwiched between the hard layer 111 and the adherence reduction layer 117. When the flexible cover 11 only includes the protective layer 115 sandwiched between the hard layer 111 and the adherence reduction layer 117, the hard layer 111 is formed by coating a hard coating material on the protective layer 115.

The substrate 113 is made of polyethylene terephthalate (PET). It is understandable that, substrate 113 includes organic compounds such as PET, polyimide (PI), cyclo-olefin polymer (COP), polymethyl methacrylate (PMMA), polymethyl methacrylate, epoxy compounds, organic alcohol esters, and inorganic materials such as thinned glass.

The protective layer 115 is used to reduce energy transmission. In at least one implementation, the protective layer 115 is used to reduce energy transfer along a stacking direction of the flexible cover 11. The stacking direction is a direction of stacking various layer structures of the flexible cover 11. In the implementation, the stacking direction is a direction in which the hard layer 111, the substrate 113, the optical adhesive layer 114, the protective layer 115, and the adherence reduction layer 117 are stacked. The protective layer 115 is adhered to the substrate 113 via the optical adhesive layer 114, to prevent excessive energy from entering the flexible module 13, avoiding damage to function/performance of a function device(s) of the flexible module 13. The adherence reduction layer 117 is adhered between the flexible module 13 and the protective layer 115, for attaching the flexible cover 11 to the flexible module 13. In the implementation, the flexible cover 11 can be prepared with different thicknesses according to product requirements (e.g., the flexible cover has a thickness of 200 μm or less), and the hard layer 111 and the adherence reduction layer 117 can be prepared with different thicknesses according to product requirements (e.g., the flexible component has a thickness of 50 μm or less).

In at least one implementation, an adhesion force of the adherence reduction layer 117 is decreased in response to a first condition and the adhesion force remains unchanged when the first condition is not met. The first condition is applied to provide energy to the adherence reduction layer 117, to decrease the adhesion force of the adherence reduction layer 117 to the flexible module 13, so that the adherence reduction layer 117 can be easily peeled from the flexible module 13. In the implementation, after the first condition is applied, the adhesion force of the adherence reduction layer 117 to the flexible module 13 drops from 0.1˜3 kg/inch to 100 g/inch or less, for example, 8 g/inch, 36 g/inch, to ensure that the flexible cover 11 can be easily detached from the flexible module 13. The detaching manner can adopt manual film-tearing or automatic mechanized film-tearing. The film tearing angle is within a range of 10˜80 degrees (e.g., 30˜60 degrees), and the film tearing speed is within a range of 100˜1000 mm/min (e.g., 300˜600 mm/min). Under this condition, no damage is caused to the flexible module 13 or part of the adherence reduction layer 117 remains on the flexible module 13.

Applying the first condition includes the following. Put the adherence reduction layer 117 in a light field (such as ultraviolet light/infrared light/laser irradiation), and the adherence reduction layer 117 will absorb a certain amount of energy, such that the adhesion force of the adherence reduction layer 117 to the flexible module 13 is decreased. Alternatively, put the adherence reduction layer 117 in an electric field (applying current and voltage, electricity generating heat), and the adherence reduction layer 117 will absorb a certain amount of energy, such that the adhesion force of the adherence reduction layer 117 to the flexible module 13 is decreased. Alternatively, put the adherence reduction layer 117 in a magnetic field (applying a magnetic field, transforming the magnetic field into an electric field, and the electric field generating heat), and the adherence reduction layer 117 will absorb a certain amount of energy, such that the adhesion force of the adherence reduction layer 117 to the flexible module 13 is decreased. Alternatively, place the adherence reduction layer 117 in a force field, (for example, the adherence reduction layer 117 is made of a viscous piezoelectric material and when a force is applied to the piezoelectric material, the piezoelectric material generates a voltage, that is, applying an electric field to the adherence reduction layer 117), and the adherence reduction layer 117 will absorb a certain amount of energy, such that the adhesion force of the adherence reduction layer 117 to the flexible module 13 is decreased. Alternatively, heat the adherence reduction layer 117, and the adherence reduction layer 117 will absorb a certain amount of energy, such that the adhesion force of the adherence reduction layer 117 to the flexible module 13 is decreased. The first condition includes at least one of ultraviolet light irradiation, infrared light irradiation, laser irradiation, applying an electric field, applying a force field, applying a magnetic field, and heating.

In the implementation, the adherence reduction layer 117 is an ultraviolet adherence reduction layer, which can absorb ultraviolet light of a certain wavelength, for example, a wavelength in a range of 200 to 400 nm. In the implementation, the adherence reduction layer 117 is made of pressure sensitive adhesion (PSA for short). The flexible module of the PSA is made of polyacrylate (commonly known as acrylic). The polyacrylate is a polymer. When irradiated with ultraviolet light, the polyacrylate will decompose, resulting in greatly reduced adhesion force of a bonding interface of the adherence reduction layer 117, which makes it easy to be stripped from the flexible module 13.

It can be understood that, the ultraviolet adherence reduction layer can be made of other acrylic esters, for example, an acrylic ester that can release nitrogen under ultraviolet light irradiation, that is, using a gas-generating peeling mechanism to reduce the adhesion force of the adherence reduction layer 117 to the flexible module 13.

In at least one implementation, the adherence reduction layer 117 includes one of the following which is doped with photoresponsive supramolecules: acrylate, silica gel, rubber, or polyurethane, and the adhesion force is decreased when the adherence reduction layer 117 is irradiated with ultraviolet light. In at least one implementation, the adherence reduction layer includes one of acrylate, silica gel, rubber, or polyurethane, where the adhesion force is decreased because of generation of nitrogen when the acrylate is irradiated with ultraviolet light.

In at least one implementation, the adherence reduction layer 117 includes at least one of an ultraviolet adherence reduction layer, an infrared adherence reduction layer, a laser adherence reduction layer, a force adherence reduction layer, an electric adherence reduction layer, a magnetic adherence reduction layer, and a thermal adherence reduction layer. The adherence reduction layer 117 can also include other materials whose adhesion force is decreased under the action of heat, where the heat can be achieved through electrical conversion, magnetic conversion, force conversion, or the like.

In at least one implementation, the protective layer 115 includes an energy absorption layer 1151. Energy input under the first condition is absorbed via the energy absorption layer 1151. For example, reduce or decrease energy of ultraviolet light/infrared light/laser entering the flexible module 13, to reduce damage to the function/performance of the flexible module 13. The energy absorption layer 1151 is made of at least one of amorphous silicon, indium tin oxide, indium gallium zinc oxide, aluminum titanium oxide, and porous silica gel. For example, the energy absorption layer 1151 is amorphous silicon (α-Si). Since the amorphous silicon (α-Si) absorbs energy (laser/ultraviolet light irradiation) and converts it into bond energy, which promotes change of bonding between atoms, and causes change of material properties, to achieve the function of the absorption layer (absorbing light/energy, etc.).

In at least one implementation, the energy absorption layer includes one of the following added with reinforced fibers: a polyethylene terephthalate compound, a cyclo-olefin polymer, or a polymethyl methacrylate compound.

In at least one example, the energy absorption layer 1151 can also be formed by doping an organic heterocyclic compound such as hydroxybenzotriazine with a colloidal material. The chemical bonds of such organic heterocyclic compound change from a ground state (low energy level) to a non-ground state (high energy level) and generate ions when the organic heterocyclic compound is irradiated with ultraviolet light. This process is a reversible chemical bond change. Finally, the organic heterocyclic compound such as hydroxybenzotriazine can fully absorb ultraviolet light and block the ultraviolet light.

In at least one implementation, the protective layer 115 further includes a heat dissipation layer 1153 stacked with the energy absorption layer 1151. Energy input under the first condition includes heat. The heat dissipation layer 1153 is used to block heat transfer along a stacking direction of the flexible cover 11 and emit heat along a direction perpendicular to the stacking direction of the flexible cover 11. The heat dissipation layer 1153 is located between the energy absorption layer 1151 and the adherence reduction layer 117 for heat dissipation, to prevent excessive energy from entering the flexible module 13 and causing damage to the function/performance/structure of the flexible module 13. The heat dissipation layer 1153 is made of at least one of thermally conductive graphene, thermally conductive adhesive, thermally conductive silicone, thermally conductive silica gel, thermally conductive rubber, and thermally conductive molybdenum sulfide. In this way, heat dissipation/transfer in a horizontal direction and no heat dissipation/transfer in a longitudinal direction are realized, that is, heat dissipation in the two-dimensional plane direction and heat insulation in the vertical direction are realized. The longitudinal direction is a direction substantially perpendicular to the flexible cover 11, and the horizontal direction is a direction substantially parallel to the flexible cover 11.

The protective layer 115 has two energy reduction layers: the energy absorption layer 1151 and the heat dissipation layer 1153. When ultraviolet radiation is used to reduce adherence, the energy absorption layer 1151 functions as regulable ultraviolet energy firstly secondly, as the protective layer (the heat dissipation layer 1153 can function as the protective layer as well). When thermal excitation is used for adherence reduction, the heat dissipation layer 1153 plays a protective role. Therefore, the energy absorption layer 1151 and the heat dissipation layer 1153 can form double protection for the flexible module 13. It can be understood that, the energy absorption layer 1151 can be provided between the heat dissipation layer 1153 and the adherence reduction layer 117.

It can be understood that, the protective layer 115 includes at least one of the energy absorption layer 1151 and the heat dissipation layer 1153, for example, includes only the heat dissipation layer 1153. The protective layer 115 can be set according to the performance of the adherence reduction layer 117. For example, if the adherence reduction layer 117 is an infrared light adherence reduction film layer, the protective layer 115 is correspondingly set as a film layer capable of blocking infrared light, to prevent the infrared light from entering the structure below the protective layer 115. For another example, in the case that electric heating is applied to reduce adherence of the adherence reduction layer 117, the protective layer 115 can be set as a heat dissipation layer, and so on.

Furthermore, the flexible cover 11 further includes a shielding layer 119 formed on one side of the optical adhesive layer 114 away from the protective layer 115. The shielding layer 119 is disposed on an edge area of the optical adhesive layer 114 to shield wirings and other structures disposed on an edge area of the flexible module 13. As such, the appearance of the flexible component 10 is improved, thereby improving the user experience. In the implementation, an ink is coated on the optical adhesive layer 114 to form the patterned shielding layer 119, and then the substrate 113 is formed on the optical adhesive layer 114 and the shielding layer 119. It can be understood that, the shielding layer 119 can be made of other opaque materials or materials with very low light transmittance, as long as the purpose of shielding is achieved. It can be understood that, the shielding layer 119 can also be formed by coating the ink on one side of the substrate 113 away from the hard layer 111. In other words, the shielding layer 119 is a patterned shape, which can be formed on the substrate 113 of the flexible cover 11 or on other film materials.

The flexible module 13 includes at least two functional layers 130 which are stacked, and the at least two functional layers 130 include a display function layer 135 and a support layer 137. The display function layer 135 includes a polarizing layer 1351, a thin film transistor layer 1353, and an organic light emitting layer 1355 which are stacked sequentially, where the polarizing layer 1351 is disposed adjacent to the adherence reduction layer 117.

The at least two functional layers 130 further include a touch layer 131. The touch layer 131 is disposed on one side of the polarizing layer 1351 of the display function layer 135 away from the support layer 137. The touch layer 131 and the adherence reduction layer 117 are bonded together. In other words, the adherence reduction layer 117 is adhered between the touch layer 131 and the protective layer 115, and one side of the adherence reduction layer 117 away from the protective layer 115 is adhered to the touch layer 131. The touch layer 131 is used to provide a function of touch input.

After the flexible component 10 has been used for a period of time, when the flexible cover 11 needs to be replaced due to excessive wear, rupture, air bubbles, etc., apply the first condition (such as, ultraviolet light irradiation/infrared light irradiation/laser irradiation/heating/applying force/applying electricity/applying magnetism, etc.) to the flexible component 10 to provide energy. After the adherence reduction layer 117 absorbs a certain amount of energy, the adhesion force of the adherence reduction layer 117 to the flexible module 13 decreases. Thereafter, the flexible cover 11 is removed from the flexible module 13 through equipment or manually. Then a new flexible cover 11 is attached to the flexible module 13 through equipment or manually.

The hard layer 111 and the adherence reduction layer 117 are disposed on both sides of the flexible cover 11 respectively. In other words, one side of the flexible cover 11 has properties such as hardness, wear resistance, and scratch resistance, and the other side has properties such as adherence and flexibility. Therefore, the flexible cover 11 not only has the required hardness, wear resistance, and scratch resistance, but also is resistant to bending, which also extends service life of the flexible cover 11 and the flexible component 10. In addition, under the first condition (such as, ultraviolet light irradiation/infrared light irradiation/laser irradiation/heating/applying force/applying electricity/applying magnetism, etc.), the adhesion force of the adherence reduction layer 117 to the flexible module 13 is decreased, which facilitates replacement of the flexible cover 11 of the flexible component 10. Furthermore, the flexible cover 11 is provided with the protective layer 115 to prevent, in the process of providing energy to the adherence reduction layer 117, excessive energy from entering the flexible module 13 and causing damage to the function/performance of the flexible module 13.

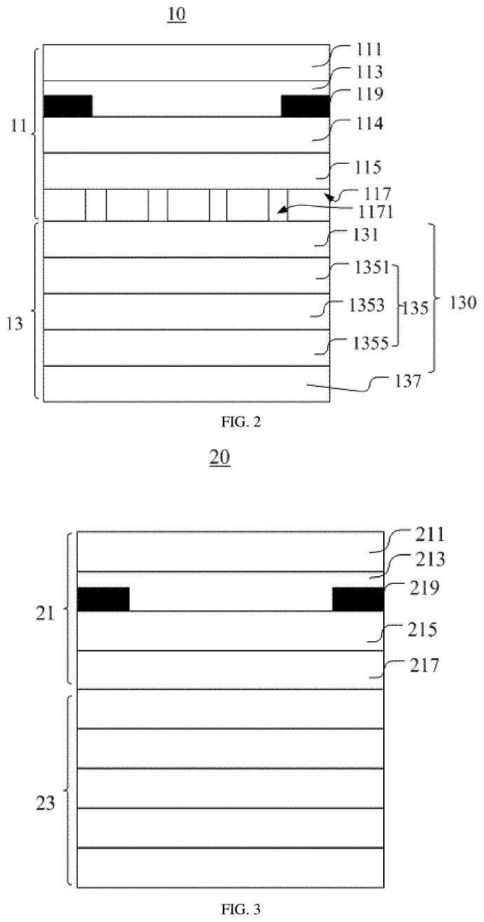

The adherence reduction layer 117 is attached as a whole or attached after patterning. In other words, an attachment shape of the adherence reduction layer 117 may be its entire surface or patterned, that is, the adherence reduction layer 117 is at least partially adhered to the flexible module 13. For example, the adherence reduction layer 117 completely covers the touch layer 131. Alternatively, referring to FIG. 2, the adherence reduction layer 117 defines at least one groove 1171, that is, the adherence reduction layer 117 is patterned. The at least one groove 1171 may or may not penetrate the entire adherence reduction layer 117. The adherence reduction layer 117 defining the at least one groove 1171 can improve flexibility of the flexible cover 11.

Referring to FIG. 3, a second implementation of the disclosure provides a flexible component 20. The flexible component 20 includes a flexible cover 21 and a flexible module 23 bonded with the flexible cover 21. The structure of the flexible cover 21 is substantially the same as the flexible cover 11 of the first implementation. The flexible cover 21 includes a hard layer 211, a substrate 213, a protective layer 215, and an adherence reduction layer 217 which are stacked sequentially. The difference is that the flexible cover 21 omits the optical adhesive layer, and the protective layer 215 directly contacts the substrate 213, thereby reducing the thickness of the flexible cover 21. The substrate 213 is made of at least one of mixtures such as polyethylene terephthalate, polyimide, cyclo-olefin polymer, polymethyl methacrylate, epoxy resin compound, organic alcohol ester, and inorganic amine, to ensure that the flexible cover 21 has sufficient strength and hardness. In the implementation, the protective layer 215 is a heat dissipation layer, which is made of at least one of thermally conductive graphene, thermally conductive adhesive, thermally conductive silicone, thermally conductive silica gel, thermally conductive rubber, and thermally conductive molybdenum sulfide. In this way, heat dissipation/transfer in a horizontal direction and no heat dissipation/transfer in a longitudinal direction are realized, that is, heat dissipation in the two-dimensional plane direction and heat insulation in the vertical direction are realized.

Furthermore, the flexible cover 21 includes a shielding layer 219 formed on the protective layer 215 away from the adherence reduction layer 217.

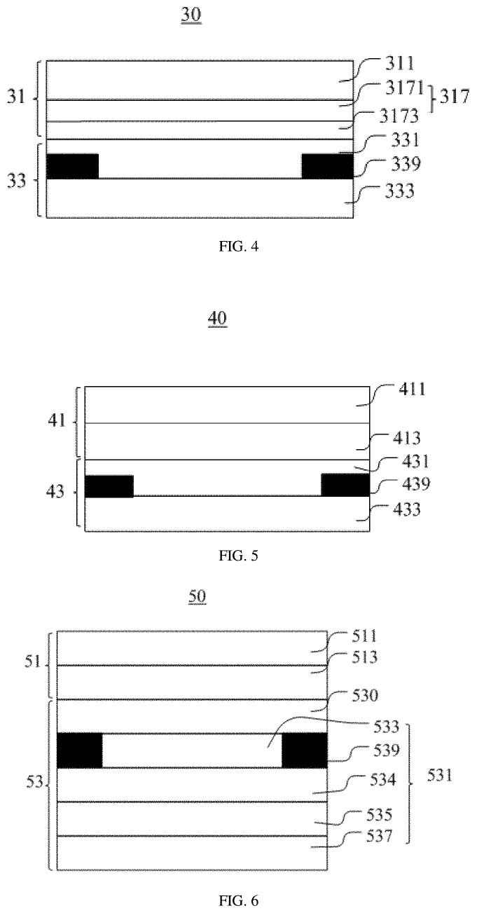

Referring to FIG. 4, a third implementation of the disclosure provides a flexible component 30. The flexible component 30 includes a flexible cover 31 and a flexible module 33. The flexible cover 31 is attached to the flexible module 33 to protect the flexible module 33.

The flexible cover 31 includes a hard layer 311 and an adherence reduction layer 317 which are stacked sequentially. In the implementation, the adherence reduction layer 317 includes a base layer 3171 and an adhesive layer 3173 which are stacked. In other words, the adherence reduction layer 317 is a single-sided adhesive, and the hard layer 311 is formed on a side of the base layer 3171 away from the adhesive layer 3173. It can be understood that, the adherence reduction layer 317 can be a double-sided adhesive layer, and the hard layer 311 is directly disposed on one of adhesive surfaces of the adherence reduction layer 317.

The flexible module 33 includes a protective layer 331 and a functional layer 333 which are stacked. The adhesive layer 3173 and one side of the protective layer 331 away from the functional layer 333 are bonded together. The protective layer 331 is used to prevent excessive energy from entering the functional layer 333, which may cause damage to the functional layer 333. The functional layer 333 may include a touch layer, a display function layer, a support layer, etc., which are stacked together, and details are not described herein.

Compared with the flexible component 10 of the first implementation, regarding to the flexible component 30 of the third implementation, since the flexible cover 31 only includes the hard layer 311 and the adherence reduction layer 317, the thickness of the flexible cover 30 can be decreased. Furthermore, the flexible cover 31 have certain hardness, wear resistance, and scratch resistance. As such, it is convenient for replacement of the flexible cover 31 of the flexible component 30. Since the protective layer 331 is placed on one side of the flexible module 33 adjacent to the flexible cover 31, excessive energy can be prevented from entering the functional layer 333 and damage to the functional layer 333 can be avoided. In addition, since the flexible cover 31 only includes the hard layer 311 and the adherence reduction layer 317, the flexible cover 31 can have a better flexibility. Since the protective layer 331 is set on the flexible module 33, it is beneficial to improve flatness of the flexible cover 31 attached to the flexible module 33 and avoid air bubbles.

Furthermore, the flexible module 33 also includes the shielding layer 339. The shielding layer 339 is formed on an edge area of a side of the protective layer 331 away from the flexible cover 31. In other words, the shielding layer 339 is set corresponding to an edge area of the functional layer 333, to shield the wirings and other structures of the flexible module 33 and improve the appearance of the flexible component 30, thereby improving the user experience. In the implementation, the shielding layer 339 is formed by coating the ink on the edge area of the side of the protective layer 331 away from the flexible cover 31.

Referring to FIG. 5, a fourth implementation of the disclosure provides a flexible component 40. The flexible component 40 includes a flexible cover 41 and a flexible module 43. The flexible cover 41 is attached to the flexible module 43 to protect the flexible module 43. The flexible cover 41 includes a hard layer 411, and the flexible module 43 includes an adherence reduction layer 431 and a functional layer 433 which are stacked. The adherence reduction layer 431 is formed on the functional layer 433. The flexible cover 41 is bonded to the flexible module 43 via the adherence reduction layer 431. Since the adherence reduction layer 431 is disposed on the flexible module 43, it is beneficial to reduce the thickness of the flexible cover 41. The functional layer 433 may include at least one of a touch layer, a display function layer, a support layer, and an optical adhesive layer.

Furthermore, the flexible module 43 includes a shielding layer 439. The shielding layer 439 is formed in an edge area of one side of the adherence reduction layer 431 away from the flexible cover 41. In other words, the shielding layer 439 is set corresponding to an edge area of the functional layer 433.

Furthermore, the flexible cover 41 includes a substrate 413. In the implementation, the hard layer 411 is formed on the substrate 413. It can be understood that, the substrate 413 can be replaced with at least one of an optical adhesive layer and a protective layer.

Referring to FIG. 6, a fifth implementation of the disclosure provides a flexible component 50. The flexible component 50 includes a flexible cover 51 and a flexible module 53, and the flexible display cover 51 includes a substrate 511 and an adherence reduction layer 513 which are stacked. The flexible module 53 includes a protective layer 530 and at least one functional layer 531. The at least one functional layer 531 includes a first optical adhesive layer 533, a touch layer 534, a second optical adhesive layer 535, and a display function layer 537 which are sequentially stacked. The protective layer 530 and the adherence reduction layer 513 are bonded together.

It can be understood that, the thickness of each layer of the flexible cover 51, the thickness of the protective layer 530 of the flexible module 53, and the thickness of each functional layer are set according to actual applications.

In the implementation, the adherence reduction layer 513 is an ultraviolet adherence reduction layer, which can absorb ultraviolet light of a certain wavelength, for example, a wavelength in a range of 200 to 400 nm. In the implementation, the adherence reduction layer 513 is made of pressure sensitive adhesion. The flexible module of the pressure sensitive adhesion is made of polyacrylate. When irradiated by ultraviolet light, the polyacrylate will decompose, so that the adherence reduction layer 513 is easily peeled off from the flexible module 53. It can be understood that, the ultraviolet adherence reduction layer can be made of other acrylic esters, for example, an acrylic ester that can release nitrogen under ultraviolet light irradiation, that is, using a gas-generating peeling mechanism to decrease the adhesion force of the adherence reduction layer 513 to the flexible module 53.

The protective layer 530 includes an ultraviolet (UV) light absorption layer. In the implementation, the protective layer 530 is made of PET. PET has excellent mechanical properties and friction and wear properties. By adding reinforced fibers (such as UV absorbers) to PET, heat resistance and UV resistance properties of PET are improved, thereby preventing excessive UV light from entering structures below the protective layer 530. It can be understood that, adding different additives to PET or blending PET with other materials (for example, forming a polymer alloy by blending) can improve performance of PET and enhance the required performance, such as, heat dissipation performance, UV resistance, infrared resistance, etc. It can be understood that, the protective layer 530 is made of at least one of the following added with reinforced fibers: PET, PI, COP, and PMMA.

The protective layer 530 can be set according to the performance of the adherence reduction layer 513. For example, if the adherence reduction layer 513 is an infrared light adherence reduction film layer, the protective layer 530 is correspondingly set as a film layer capable of blocking infrared light, to prevent the infrared light from entering the structure below the protective layer 530. For another example, in the case that electric heating is applied to reduce adherence of the adherence reduction layer 513, the protective layer 530 can be set as a heat dissipation layer, and so on.

In an example, referring to FIG. 7, the flexible cover 51 also includes a release film 515. The release film layer 515 covers one side of the adherence reduction layer 513 away from the substrate 511 and is used to protect the adherence reduction layer 513. It is possible to avoid the adherence reduction layer 513 from being contaminated (that is, adhesion of other foreign matters) when the flexible cover 51 is not attached to the flexible module 53 (for example, when the flexible cover 51 is not in use). That is, avoid poor fit of the adherence reduction layer 513 to the flexible module 53, and avoid affecting the use of the flexible component 50.

Furthermore, the flexible cover 51 includes a hard layer 517, and the hard layer 517 is disposed on a side of the substrate 511 away from the adherence reduction layer 513. In the implementation, the hard layer 517 can be formed by coating a hard coating material on the side of the substrate 511 away from the adherence reduction layer 513. The coating technology may be: roll to roll coating, spin coating, slit and spin coating, slit coating, etc. When the hard layer 517 is made of organic compound, a CVD technology or a PVD technology can be used. When the hard layer 517 is made of conductive material, technologies such as sputtering, ink jet printing, screen printing, and the like can be used.

Furthermore, the flexible cover 51 includes a protective film layer 519. The protective film layer 519 covers one side of the hard layer 517 away from the substrate 511, for protecting the hard layer 517. This prevents the hard layer 517 of the flexible cover 51 from being worn and scratched (for example, when the flexible cover 51 is not in use), which affects the appearance of the flexible component 50.

Furthermore, referring to FIG. 6, the flexible module 53 includes a shielding layer 539. The shielding layer 539 is formed on an edge area of a side of the protective layer 530 away from the flexible cover 51, and the shielding layer 539 is disposed around the first optical adhesive layer 533. In the implementation, the shielding layer 539 is formed by printing ink on the edge area of the side of the protective layer 530 away from the flexible cover 51, such that the protective layer 530 and the shielding layer 539 can be well combined together.

The adherence reduction layer 513 is added to the flexible cover 51. The adherence reduction layer 513 ensures that the flexible cover 51 can be easily separated from the flexible module 53. In addition, the protective layer 530 is added to one side of the flexible module 53 adjacent to the flexible cover 51. The protective layer 530 can avoid excessive energy from entering the functional layer 531 and structures under the protective layer 530 in the process of ultraviolet light/infrared light/laser irradiation, which causes excessive temperature and affects the performance and function of each functional layer 550, or harms the structure of each functional layer 550. Alternatively, under the action of thermal excitation, the protective layer 530 only transfers heat horizontally, so as to prevent longitudinal heat transfer from affecting the performance and function of each functional layer 550 or from harming the structure of each functional layer 550. Furthermore, in the process of separating the flexible cover 51 from the flexible module 53, the protective layer 530 can prevent other functional layers 531 under the protective layer 530 from being stuck by the adherence reduction layer 513, thereby protecting them.

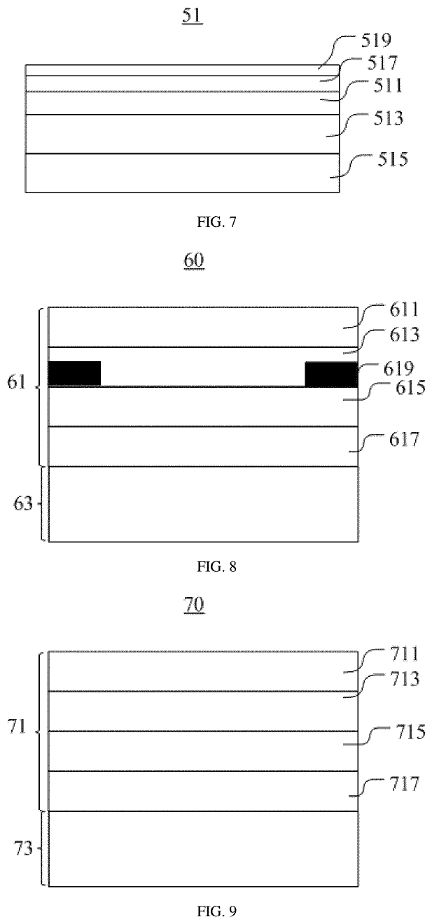

Referring to FIG. 8, a sixth implementation of the disclosure provides a flexible component 60. The flexible component 60 includes a flexible cover 61 and a flexible module 63. The flexible cover 61 is attached to the flexible module 63 to protect the flexible module 63. The structure of the flexible cover 61 is substantially the same as that of the flexible cover 21 of the second implementation. The flexible cover 61 includes a hard layer 611, an optical adhesive layer 613, a protective layer 615, and an adherence reduction layer 617 which are stacked sequentially. The difference between the flexible cover 61 and the flexible cover 21 is that the substrate 213 is replaced with an optical adhesive layer 613. The flexible cover 61 has excellent bending performance and cost of flexible cover 61 can be reduced.

Furthermore, the flexible cover 61 includes a shielding layer 619 formed on the protective layer 615. The shielding layer 619 is formed on one side of the protective layer 615 away from the adherence reduction layer 617.

Referring to FIG. 9, a seventh implementation of the disclosure provides a flexible component 70. The flexible component 70 includes a flexible cover 71 and a flexible module 73. The flexible cover 71 is attached to the flexible module 73 to protect the flexible module 73. The structure of the flexible cover 71 is substantially the same as the flexible cover 21 of the second implementation. The flexible cover 71 includes a hard layer 711, a protective layer 713, a substrate 715, and an adherence reduction layer 717 which are stacked in sequence. The difference between the flexible cover 71 and the flexible cover 21 is that the substrate 715 is sandwiched between the protective layer 713 and the adherence reduction layer 717.

With regard to the flexible component 10 of the first implementation, the flexible component 20 of the second implementation, the flexible component 30 of the third implementation, the flexible component 40 of the fourth implementation, the flexible component 50 of the fifth implementation, the flexible component 60 of the sixth implementation, and the flexible component 70 of the seventh implementation, the adherence reduction layer can be disposed either on the flexible cover or on the flexible module. In other words, one of the flexible cover and the flexible module includes the adherence reduction layer, to adhere the flexible cover to the flexible module.

It is understandable that, the protective layer can be disposed on the flexible cover or on the flexible module. In other words, at least one of the flexible cover and the flexible module includes the protective layer, to avoid excessive energy entering the flexible module, which will affect the structure/function/performance of the flexible module, and thus affect quality of the flexible component.

In summary, according to the flexible component, the adherence reduction layer and the protective layer are stacked. That is, the adherence reduction layer can be directly or indirectly stacked with the protective layer. In other words, the adherence reduction layer may or may not be in direct contact with the protective layer.

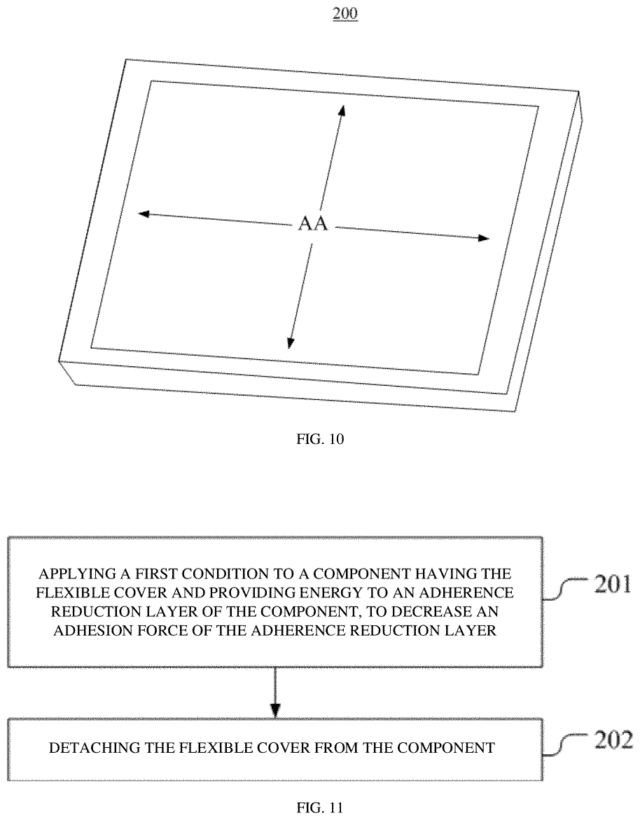

Referring to FIG. 10, the disclosure also provides an electronic device 200 with a flexible component. The flexible component may be the flexible component 10 of the first implementation, the flexible component 20 of the second implementation, the flexible component 30 of the third implementation, the flexible component 40 of the fourth implementation, the flexible component 50 of the fifth implementation, the flexible component 60 of the sixth implementation, or the flexible component 70 of the seventh implementation. The electronic device 200 may be a mobile phone, a tablet computer, a TV, a reader, a navigator, a game console, and the like.

Referring to FIG. 11, a method for detaching a flexible cover is provided. The method includes the following blocks.

At block 201, a first condition is applied to a component having the flexible cover and energy is provided to an adherence reduction layer of the component, to decrease an adhesion force of the adherence reduction layer. The first condition includes at least one of: ultraviolet light irradiation, infrared light irradiation, laser irradiation, applying an electric field, applying a force field, applying a magnetic field, and heating.

At block 202, the flexible cover is detached from the component.

The component is the above flexible component, the component includes the above flexible module, and the flexible cover is bonded to the flexible module via the adherence reduction layer. It can be understood that, in an example, the component may include a flexible cover and a rigid module, for example, a rigid display module, or a rigid touch module, or a rigid display touch module, etc.

In at least one implementation, the adhesion force of the adherence reduction layer is decreased as follows. The adhesion force of the adherence reduction layer is decreased from 0.1˜3 kg/inch to 100 g/inch or less.

In at least one implementation, the flexible cover is detached from the component as follows. The flexible cover is detached from the component through manual film-tearing or automatic mechanized film-tearing, and an angle at which the flexible cover is torn off from the component is in a range of 10 to 80 degrees (e.g., 30 to 60 degrees). Under the above condition, no harm is caused to the component or part of the adherence reduction layer remains on the component.

In at least one implementation, a speed at which the flexible cover is torn off from the component is in a range of 100 to 1000 mm/min (e.g., 300 to 600 mm/min).

The above are some implementations of this application. It should be noted that, for those of ordinary skill in the art, without departing from the principles of this application, improvements and modifications can be made, and these improvements and modifications are also deemed to be within the protection scope of this application.

What is claimed is:

1. A flexible component comprising an adherence reduction layer for bonding.

2. The flexible component of claim 1, wherein the adherence reduction layer has an adhesion force which is decreased in response to a first condition.

3. The flexible component of claim 2, wherein the first condition comprises at least one of: ultraviolet light irradiation, infrared light irradiation, laser irradiation, applying an electric field, applying a force field, applying a magnetic field, and heating.

4. The flexible component of claim 1, wherein the adherence reduction layer comprises one of the following which is doped with photoresponsive supramolecules: acrylate, silica gel, rubber, or polyurethane, and the adhesion force is decreased when the adherence reduction layer is irradiated with ultraviolet light.

5. The flexible component of claim 1, wherein the adherence reduction layer comprises one of: acrylate, silica gel, rubber, or polyurethane, wherein the adhesion force is decreased because of generation of nitrogen when the acrylate is irradiated with ultraviolet light.

6. The flexible component of claim 1, wherein the flexible component further comprises a protective layer, and the adherence reduction layer and the protective layer are stacked.

7. The flexible component of claim 6, wherein the protective layer comprises an energy absorption layer, energy input under the first condition being absorbed via the protective layer.

8. The flexible component of claim 7, wherein the energy absorption layer comprises one of the following added with reinforced fibers: a polyethylene terephthalate compound, a cyclo-olefin polymer, or a polymethyl methacrylate compound.

9. The flexible component of claim 8, wherein the energy absorption layer is doped with organic heterocyclic compounds.

10. The flexible component of claim 6, wherein the protective layer comprises a heat dissipation layer, energy input under the first condition comprising heat, wherein the heat dissipation layer is used to block heat transfer along a stacking direction of the protective layer relative to the adherence reduction layer and emit heat along a direction perpendicular to the stacking direction of the protective layer relative to the adherence reduction layer.

11. The flexible component of claim 6, wherein the flexible component comprises a flexible cover and a flexible module which are stacked, wherein the flexible cover or the flexible module comprises the adherence reduction layer and the flexible cover is adhered to the flexible module via the adherence reduction layer.

12. The flexible component of claim 11, wherein the protective layer is located in the flexible cover and is located on one side of the adherence reduction layer away from the flexible module.

13. The flexible component of claim 12, wherein the flexible cover further comprises a substrate, wherein the substrate is sandwiched between the adherence reduction layer and the protective layer.

14. The flexible component of claim 12, wherein the flexible cover further comprises a substrate, wherein the substrate is disposed on one side of the protective layer away from the adherence reduction layer.

15. The flexible component of claim 11, wherein the protective layer is located in the flexible module and the adherence reduction layer is located on one side of the protective layer adjacent to the flexible cover.

16. The flexible component of claim 15, wherein the flexible module further comprises an optical adhesive layer, wherein the optical adhesive layer is located on one side of the protective layer away from the flexible cover.

17. The flexible component of claim 16, wherein the flexible cover further comprises a shielding layer, wherein the shielding layer is formed on one side of the protective layer away from the adherence reduction layer and has a patterned shape.

18. The flexible component of claim 11, wherein the flexible cover further comprises an optical adhesive layer, wherein the optical adhesive layer is disposed on one side of the adherence reduction layer away from the flexible module.

19. The flexible component of claim 11, wherein the flexible module further comprises a shielding layer, wherein the shielding layer is formed on one side of the protective layer away from the flexible cover and has a patterned shape.

20. The flexible component of claim 11, wherein the flexible module further comprises at least one functional layer, wherein the at least one functional layer is disposed on one side of the protective layer away from the adherence reduction layer.

21. The flexible component of claim 20, wherein the at least one functional layer comprises a display function layer.

22. The flexible component of claim 20, wherein the at least one functional layer comprises a touch layer.

23. The flexible component of claim 11, wherein the flexible module comprises a display function layer and a support layer which are stacked, wherein the display function layer is disposed between the adherence reduction layer and the support layer.

24. The flexible component of claim 23, wherein the display function layer comprises a polarizing layer, a thin film transistor layer, and an organic light emitting layer which are stacked sequentially, wherein the polarizing layer is disposed adjacent to the adherence reduction layer.

25. The flexible component of claim 23, wherein the flexible module further comprises a touch layer, wherein the touch layer is disposed on one side of the display function layer away from the support layer and is bonded with the adherence reduction layer.

26. An electronic device comprising the flexible component of claim 1.

27. A method for detaching a flexible cover, comprising:
applying a first condition to a component having the flexible cover and providing energy to an adherence reduction layer of the component, to decrease an adhesion force of the adherence reduction layer; and
detaching the flexible cover from the component.

28. The method of claim 27, wherein the first condition comprises at least one of: ultraviolet light irradiation, infrared light irradiation, laser irradiation, applying an electric field, applying a force field, applying a magnetic field, and heating.

29. The method of claim 27, wherein the component comprises a flexible module and the flexible cover is bonded to the flexible module via the adherence reduction layer.
